(19) United States
(12) Patent Application Publication
(10) Pub. No.: US 2005/0186695 A1
(43) Pub. Date: Aug. 25, 2005

(54) Method for manufacturing solid-state imaging device

(75) Inventor: Tohru Yamada, Kyoto-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 11/049,029

(22) Filed: Feb. 1, 2005

(30) Foreign Application Priority Data
Feb. 23, 2004 (JP) 2004-046793

(51) Int. Cl. H01L 29/768

(52) U.S. Cl. 438/48

(57) ABSTRACT

First, a first gate insulating film is formed in a region where a charge transfer portion is to be formed on a semiconductor substrate, and a protective film is formed on the first gate insulating film. A photoresist for transfer channel formation is formed on the protective film, and then a part of the photoresist for the transfer channel formation is removed by patterning. Next, an impurity is ion-implanted using the photoresist for the transfer channel formation as a mask, so as to form a transfer channel below the first gate insulating film. Subsequently, the photoresist for the transfer channel formation is removed, and the second gate insulating film is formed on the protective film. Thereafter, a transfer electrode is formed.

### FIELD OF THE INVENTION

The present invention relates to a method for manufacturing a solid-state imaging device, in particular, a method for manufacturing a charge transfer device that composes a solid-state imaging device.

### BACKGROUND OF THE INVENTION

Recently, due to the rapid spread of digital cameras, digital movie cameras and camera-equipped mobile phones, demands for solid-state imaging devices have been grown sharply. FIG. 6 shows a configuration of a conventional solid-state imaging device schematically. FIG. 7 is an enlarged view showing a configuration of a pixel of the solid-state imaging device shown in FIG. 6.

As shown in FIG. 6, the solid-state imaging device includes plural pixels 72 disposed in a matrix in a photoreceptive region 70 on a silicon substrate 71. Since the solid-state imaging device shown in FIG. 6 adopts an interline transfer, each of the pixels 72 is provided with a vertical CCD (charge coupled device) 73 and a photodiode 74.

In addition, a horizontal CCD 88 is formed adjacent to the vertical CCD 73 in the final row, and an output amplifier 86 is provided at an output terminal of the horizontal CCD 88. The vertical CCD 73 and the horizontal CCD 88 function as charge transfer devices.

As shown in FIG. 7, the vertical CCD 73 is formed of a n-channel 78, a first transfer electrode 79 and a second transfer electrode 80. The photodiode 74 is formed of a n-region (a photoelectric conversion portion) 75.

Moreover, a p-region (a readout portion) 77 is formed between the n-channel 78 and the n-region 75. A signal charge that is photoelectrically converted by the n-region 75 is read out to the n-channel 78 by the p-region 77. Furthermore, a p-region 76 functioning as element isolation is formed around the n-region 75 excluding in the p-region 77. The first transfer electrode 79 and the second transfer electrode 80 are formed on the n-channel 78, the p-channel 77 and the p-region 76, which are shown by hatching in FIG. 7.

The operation of the solid-state imaging device shown in FIGS. 6 and 7 will be described. First, when an optical image is formed in the photoreceptive region 70, each photodiode 74 performs photoelectric conversion and accumulates a signal charge according to an intensity and a time of light. Here, when a high-level voltage (10 V to 15 V) is applied to the second transfer electrode 80, the signal charge accumulated in each of the photodiodes 74 is transferred to the vertical CCD 73 via the p-region (the readout portion) 77.

Next, when a middle-level voltage (0 V) and a low-level voltage (−5 V to −10 V) are applied alternately to the first transfer electrode 79 and the second transfer electrode 80, the signal charge is transferred from the vertical CCD 73 to the horizontal CCD 88.

Subsequently, when a high-level voltage (2 V to 5 V) and a low-level voltage (0 V) are applied alternately to the horizontal CCD 88, the signal charge is transferred from the horizontal CCD 88 to the output amplifier 86. The output amplifier 86 converts the signal charge into a voltage, and then outputs the signal voltage to outside.

As mentioned above, in the solid-state imaging device, the signal charge accumulated in the photodiode 74 is transferred by the vertical CCD 73, and subsequently is output to outside by the horizontal CCD 88. Charge transfer characteristics and saturation characteristics of the vertical CCD 73 are particularly important to realize a higher performance of the solid-state imaging device and to increase the number of pixels thereof.

Next, a method for manufacturing the solid-state imaging device shown in FIGS. 6 and 7, in particular, the vertical CCD 73 will be described with reference to FIGS. 8A to 9G (see, for example, JP58-86770A). FIGS. 8A to 9G are cross-sectional views showing a method for manufacturing a conventional solid-state imaging device. FIGS. 8A to 8D show a series of main steps, and FIGS. 9E to 9G show a series of steps that are subsequent to the step of FIG. 8D.

Here, FIGS. 8A to 9G show the respective manufacturing steps, each showing a cross sectional configuration taken along a line A-A: in FIG. 7. FIGS. 8A, 8B, 8D and 9E include diagrams showing impurity distributions in a depth direction of the silicon substrate 71, with the accompanying cross-sectional views.

First, as shown in FIG. 8A, a protective oxide film 81 (thickness: 20 nm) is formed on a n-type silicon substrate (hereinafter, called a n-type substrate) 71 by thermal oxidation or the like. Moreover, a photoresist (not shown in the figures) is formed on the protective oxide film 81, and then a part of the photoresist overlapping with a region where a p-type well 82 is to be formed is removed. Thereafter, the p-type well 82 is formed by ion-implantation of a p-type impurity, for example, boron (B).

Next, the photoresist formed in the step of FIG. 8A is removed completely. Thereafter, as shown in FIG. 8B, a photoresist 83 is formed on the protective oxide film 81, and then a part of the photoresist 83 overlapping with a region where a p-region 76 is to be formed is removed. Subsequently, a p-type impurity, for example, boron (B) is ion-implanted. Thereby, the p-region 76 (see FIG. 7) is formed in a region shallower than the p-type well 82.

Thereafter, as shown in FIG. 8C, the photoresist 83 is removed completely, and then the protective oxide film 81 also is removed completely. Here, the removal of the protective oxide film 81 is conducted, for example, by wet etching using an etching solution or the like that contains hydrofluoric acid as a main component.

Subsequently, as shown in FIG. 8D, a first gate insulating film (a silicon oxide film) 84 is formed on the n-type substrate 71 by thermal oxidation or the like. Here, the p-region 76 diffuses due to a high-temperature heat treatment for forming the first gate insulating film 84, which is indicated by FIG. 8D. Thus, an effective channel width of the below-mentioned n-channel (see FIG. 9E) decreases accordingly.

Next, as shown in FIG. 9E, a photoresist 85 is formed on the first gate insulating film 84, and then a part of the photoresist 85 overlapping with a region where a n-channel (a transfer channel) 78 is to be formed is removed. Subsequently, a n-type impurity such as phosphorus (P) and arsenic (As) is ion-implanted. Thereby, the n-channel 78 (see FIG. 7) is formed.

Thereafter, the photoresist 85 is removed completely as shown in FIG. 9F. The removal of the photoresist 85 is conducted by using a photoresist removal solution containing, for example: sulfuric acid and a hydrogen peroxide solution; or ammonia and a hydrogen peroxide solution, as main components.

Subsequently, as shown in FIG. 9G, a second gate insulating film (a silicon nitride film) 87 is formed on the first gate insulating film 84, and a first transfer electrode 79 (see FIG. 7) is formed further on the second gate insulating film 87. Thereby, the vertical CCD 73 shown in FIGS. 6 and 7 can be manufactured.

An example of forming the first gate insulating film 84 after the formation of the n-channel 78 is disclosed in Albert J. P. Theuwissen, “Solid-State Imaging with Charge-Coupled Devices”, SOLID-STATE SCIENCE AND TECHNOLOGY LIBRARY, 1995, pp. 320-327. On the other hand, in the manufacturing method shown by FIGS. 8A to 9G, the n-channel 78 is formed after the formation of the first gate insulating film 84 as mentioned above (see FIGS. 8D and 9E).

According to the manufacturing method shown by FIGS. 8A to 9G, the high-temperature heat treatment during the formation of the first gate insulating film 84 hardly causes the n-type impurity to diffuse toward the outside or to be absorbed by the first gate insulating film 84. Thus, a reduction in saturation charge capacity of the n-channel 78 can be suppressed, and the occurrence of crystal defects in the n-channel 78 can be reduced. Thereby the occurrence of a white line noise that is caused by a local increase of a dark current also can be suppressed.

However, the photoresist removal solution used for removing the photoresist 85 in the step of FIG. 9F tends to corrode a silicon oxide film. Therefore, as shown in FIG. 9F, the thickness of the first gate insulating film 84 is reduced in a process of removing the photoresist 85. More specifically, the thickness of the first gate insulating film 84 is reduced by approximately 1 nm in one photoresist removal process, which depends on the condition of the photoresist removal solution, though.

The photoresist process may be repeated in the case where in-process discrepancies occur, or further photoresist processes may be added for ion-implantations of other impurities. In these cases, the thickness of the first gate insulating film 84 is further reduced in accordance with the number of the photoresist removal processes that are actually performed.

When the thickness of the first gate insulating film 84 is reduced as mentioned above, it is difficult to control the total thickness of the gate insulating films, and the unevenness of the thickness becomes larger. As a result, charge transfer characteristics and saturation characteristics of the vertical CCD 73 are adversely affected, thus leading to a loss of qualities of images obtained by the solid-state imaging device.

### SUMMARY OF THE INVENTION

It is an object of the present invention to provide a method for manufacturing a solid-state imaging device that can solve the above-described problems and can suppress thinning of a gate insulating film.

In order to attain the above-mentioned object, the solid-state imaging device manufacturing method of the present invention is for manufacturing a solid-state imaging device including a semiconductor substrate having a photodiode and a charge transfer portion, and the charge transfer portion being provided with a transfer channel. The method includes the steps of: (a) forming a first gate insulating film in a region where the charge transfer portion is to be formed on the semiconductor substrate; (b) forming a protective film on the first gate insulating film; (c) forming a photoresist for transfer channel formation on the protective film and removing a part of the photoresist for the transfer channel formation overlapping with a region where the transfer channel is to be formed; (d) forming the transfer channel below the first gate insulating film by ion-implantation of an impurity using the photoresist for the transfer channel formation as a mask; (e) removing the photoresist for the transfer channel formation; and (f) forming a second gate insulating film on the protective film after the step (e).

As mentioned above, according to the method for manufacturing the solid-state imaging device of the present invention, the protective film is formed on the first gate insulating film, and the photoresist for the transfer channel formation is formed further on the protective film. Thus, in the process of removing the photoresist by etching, the first gate insulating film is protected by the protective film from a resist removal solution. Accordingly, since the thinning of the first gate insulating film is suppressed, the total thickness of the gate insulating films can be controlled easily, and the unevenness of the thickness can be decreased. As a result, saturation characteristics and charge transfer characteristics of the charge transfer portion (a charge transfer device) of the solid-state imaging device can be stabilized, and moreover, can be improved.

### BRIEF DESCRIPTION OF THE DRAWINGS

FIGS. 1A to 1D are cross-sectional views showing respective steps in the method for manufacturing the solid-state imaging device according to Embodiment 1 of the present invention. FIGS. 1A to 1D respectively show a series of the main steps.

FIGS. 2E to 2H are cross-sectional views showing respective steps in the method for manufacturing the solid-state imaging device according to Embodiment 1 of the present invention. FIGS. 2E to 2H respectively show a series of the main steps that are subsequent to the step of FIG. 1D.

FIGS. 3A and 3B are cross-sectional views showing respective steps in the method for manufacturing the solid-state imaging device according to Embodiment 2 of the present invention. FIGS. 3A and 3B respectively show a series of the main steps.

FIGS. 4A to 4C are cross-sectional views showing respective steps in the method for manufacturing the solid-state imaging device according to Embodiment 3 of the present invention. FIGS. 4A to 4C respectively show a series of the main steps.

FIGS. 5D to 5F are cross-sectional views showing respective steps in the method for manufacturing the solid-state imaging device according to Embodiment 3 of the present invention. FIGS. 5D to 5F respectively show a series of the main steps that are subsequent to the step of FIG. 4C.

FIG. 6 is a schematic view showing a configuration of the conventional solid-state imaging device.

FIG. 7 is an enlarged view showing a configuration of a pixel of the solid-state imaging device shown in FIG. 6.

FIGS. 8A to 8D are cross-sectional views showing respective steps in the method for manufacturing the conventional solid-state imaging device. FIGS. 8A to 8D respectively show a series of the main steps.

FIGS. 9E to 9G are cross-sectional views showing respective steps in the method for manufacturing the conventional solid-state imaging device. FIGS. 9E to 9G respectively show a series of the main steps that are subsequent to the step of FIG. 8D.

### BEST MODE FOR CARRYING OUT THE INVENTION

In the method for manufacturing the solid-state imaging device of the present invention, it is preferable that the protective film is removed after removing the photoresist for the transfer channel formation in the step (e), and the second gate insulating film is formed on the first gate insulating film in the step (f). Here, the protective film preferably is removed using an etching solution that provides a higher etch rate with respect to the protective film than with respect to the first gate insulating film.

Alternatively, in the method for manufacturing the solid-state imaging device of the present invention, the transfer channel may be first conductive-type, to which a first conductive-type impurity may be ion-implanted in the step (d).

Additionally, the above-stated solid-state imaging device may include a second conductive-type region formed on one or both sides of the transfer channel of the semiconductor substrate. The method for manufacturing the solid-state imaging device preferably includes the further steps of: (g) forming a photoresist for second conductive-type region formation on the protective film and removing a part of the photoresist for the second conductive-type region formation overlapping with a region where the second conductive-type region is to be formed; (h) forming the second conductive-type region below the first gate insulating film by ion-implantation of a second conductive-type impurity using the photoresist for the second conductive-type region formation as a mask; and (i) removing the photoresist for the second conductive-type region formation. Here, the steps (g) to (i) preferably are conducted after the step (b) or (e) and before the step (i).

In this case, it is further preferable to conduct the steps (g) to (i) after the steps (c) to (e) when a mass number of the first conductive-type impurity is smaller than that of the second conductive-type impurity, and to conduct the steps (c) to (e) after the steps (g) to (i) when a mass number of the first conductive-type impurity is larger than that of the second conductive-type impurity.

Moreover, in the method for manufacturing the solid-state imaging device of the present invention, the protective film preferably is formed to have a thickness smaller than a thickness of the first gate insulating film and a thickness of the second gate insulating film in the step (b).

In the method for manufacturing the solid-state imaging device of the present invention, the photoresist for the transfer channel formation preferably is removed using a photoresist removal solution that provides a lower etch rate with respect to the protective film than with respect to the first gate insulating film in the step (e). In addition, the photoresist for the second conductive-type region formation preferably is removed using a photoresist removal solution that provides a lower etch rate with respect to the protective film than with respect to the first gate insulating film in the step (i).

Furthermore, in the method for manufacturing the solid-state imaging device of the present invention, it is preferable that the first gate insulating film is formed of a silicon oxide film in the step (a), the protective film is formed of a silicon nitride film in the step (b), and the second gate insulating film is formed of a silicon nitride film in the step (f).

(Embodiment 1)

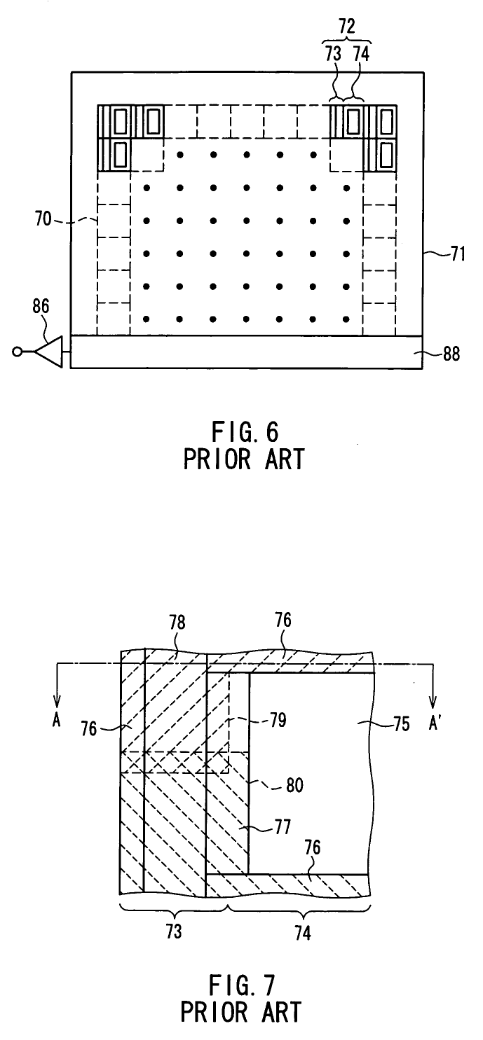

The method for manufacturing the solid-state imaging device of Embodiment 1 of the present invention will be described below. The solid-state imaging device manufactured in Embodiment 1 has the same configuration as that of the solid-state imaging device shown in FIGS. 6 and 7.

More specifically, the solid-state imaging device manufactured in Embodiment 1 includes a semiconductor substrate having a photodiode and a charge transfer portion. The charge transfer portion functions as a charge transfer device for transferring a signal charge accumulated in the photodiode to outside, and is composed of a vertical CCD and a horizontal CCD.

The vertical CCD includes a first conductive-type transfer channel, and a second conductive-type region functioning as element isolation is formed on one or both sides of the transfer channel. Note here that the first conductive-type denotes n-type, and the second-conductive type denotes p-type in Embodiment 1.

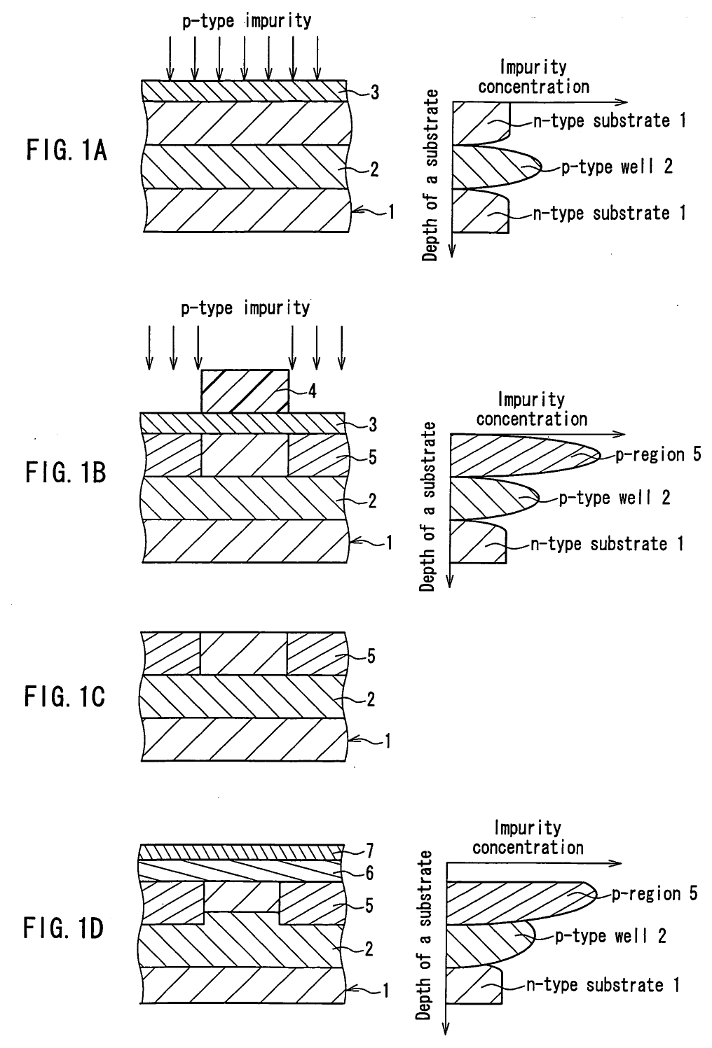

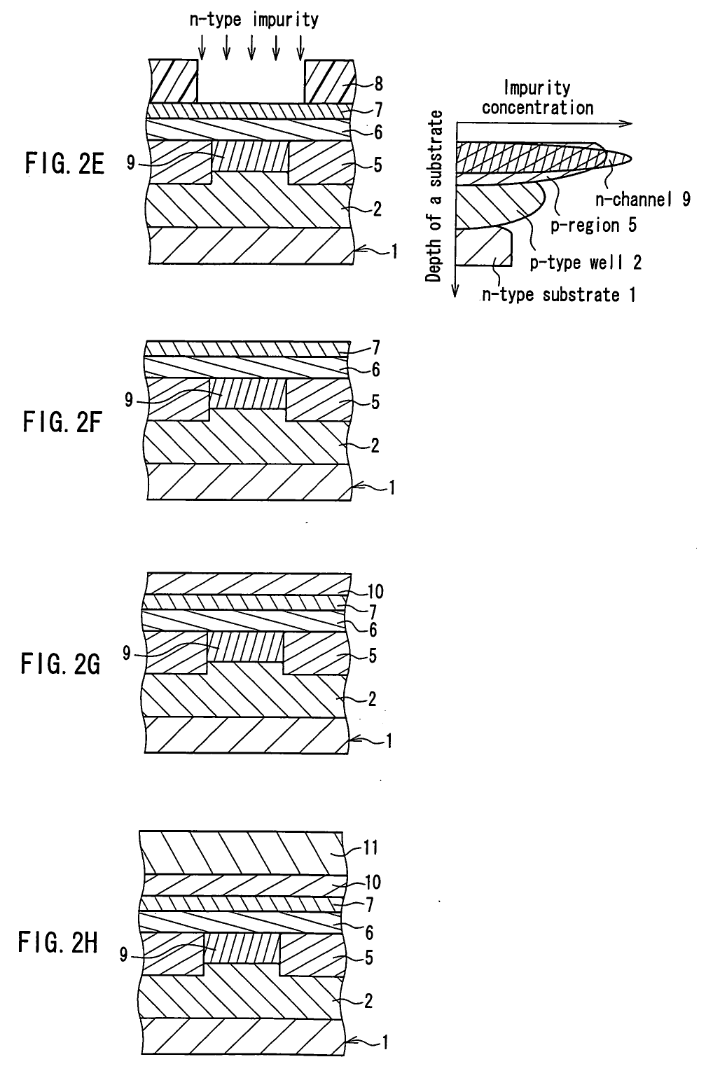

FIGS. 1A to 2H are referred to for the following description. FIGS. 1A to 2H are cross-sectional views showing respective steps in the method for manufacturing the solid-state imaging device of Embodiment 1 of the present invention. FIGS. 1A to 1D respectively show a series of the main steps. FIGS. 2E to 2H respectively show a series of the main steps that are subsequent to the step of FIG. 1D.

Similarly to FIGS. 8A to 9G, FIGS. 1A to 2H show the respective manufacturing steps, each showing a cross sectional configuration (see the line A-A in FIG. 7) of a region where the vertical CCD is provided on the semiconductor substrate. FIGS. 1A, 1B, 1D and 2E include diagrams showing impurity distributions in a depth direction of the semiconductor substrate, with the accompanying cross-sectional views.

First, as shown in FIG. 1A, a protective oxide film 3 (thickness: 20 nm) is formed on a semiconductor substrate 1 by thermal oxidation or the like. In Embodiment 1, the semiconductor substrate 1 is a first conductive-type silicon substrate (a n-type substrate) and the protective oxide film 3 is a silicon oxide film.

In addition, a photoresist (not shown in the figures) is formed on the protective oxide film 3, and then a part of the photoresist overlapping with a region where a p-type well 2 is to be formed is removed. Thereafter, a p-type impurity such as boron (B) is ion-implanted with an implantation energy of 300 keV and a dose of 1.0×10¹² ions/cm², for example. Thereby, the p-type well 2 is formed.

Next, as shown in FIG. 1B, the photoresist formed in the step of FIG. 1A is removed completely, and then a photoresist (a photoresist for p-region formation) 4 is formed for the purpose of forming a p-region (a second conductive-type region) 5 on the protective oxide film 3. Subsequently, a part of the photoresist 4 for the p-region formation overlapping with a region where the p-region 5 is to be formed is removed.

Thereafter, a p-type impurity such as boron (B) is ion-implanted with an implantation energy of 40 keV and a dose of 1.0×10¹³ ions/cm², for example. Thereby, the p-region 5 is formed in a region shallower than the p-type well 2. The p-region 5 functions as element isolation similarly to the p-region 76 shown in FIG. 7.

Next, as shown in FIG. 1C, the photoresist 4 for the p-region formation is removed completely, and then the protective oxide film 3 is also removed completely. The removal of the protective oxide film 3 is conducted by wet etching using an etching solution that contains, for example, hydrofluoric acid as a main component or the like.

Thereafter, as shown in FIG. 1D, a first gate insulating film 6 is formed on the semiconductor substrate 1 by thermal oxidation or the like, and a protective oxide film 7 is further formed on the first gate insulating film 6 by CVD or the like. In Embodiment 1, the first gate insulating film 6 is a silicon oxide film with a thickness of 30 nm. The protective film 7 is a silicon nitride film, and a thickness thereof is determined so that the protective film 7 may not be removed completely in the below-mentioned photoresist removal process (see FIG. 2G below), considering an amount of the reduction of the thickness in the photoresist removal process. A specific range of the thickness of the protective film 7 will be described below.

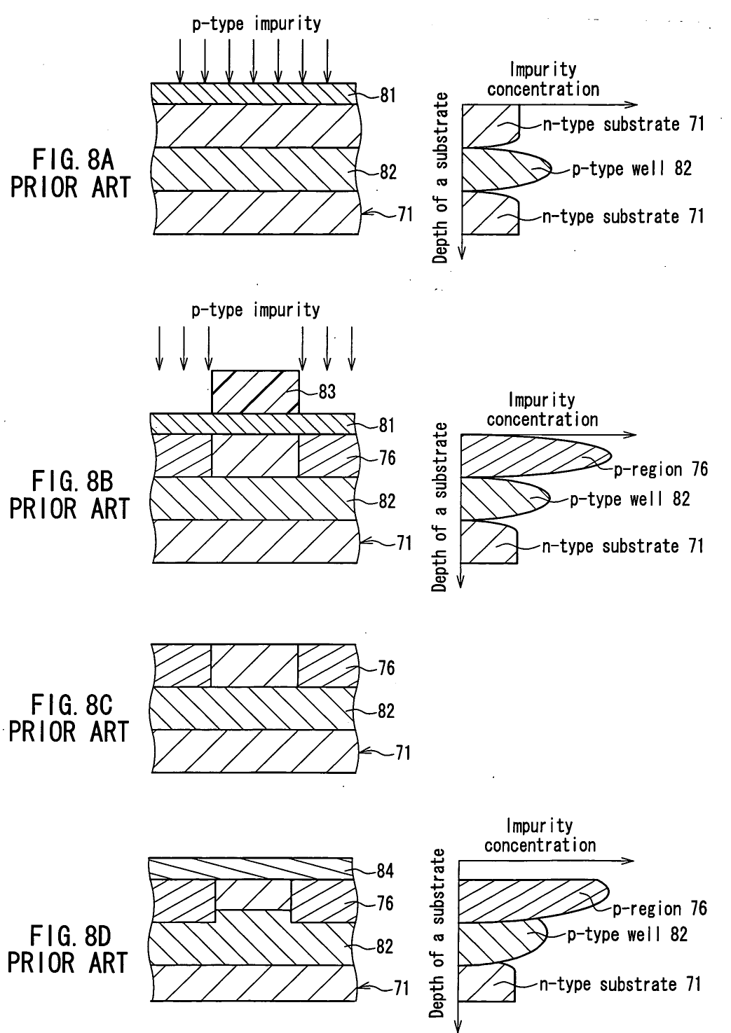

Here, as shown in FIG. 1D, the p-region 5 diffuses due to a high-temperature heat treatment (at approximately 800 to 1000° C.) for forming the first gate insulating film 6 in Embodiment 1, similarly to the step of FIG. 8D. Thus, an effective channel width of the below-mentioned n-type transfer channel (see FIG. 2E) decreases accordingly.

Next, as shown in FIG. 2E, a photoresist (a photoresist for transfer channel formation) 8 is formed on the protective film 7 for the purpose of forming a n-type transfer channel 9, and then a part of the photoresist 8 for the transfer channel formation overlapping with a region where the transfer channel 9 is to be formed is removed. Thereafter, a n-type impurity such as phosphorus (P) and arsenic (As) is ion-implanted with an implantation energy of 150 keV and a dose of 1.0×10¹³ ions/cm², for example. Thereby, the n-type transfer channel 9 is formed.

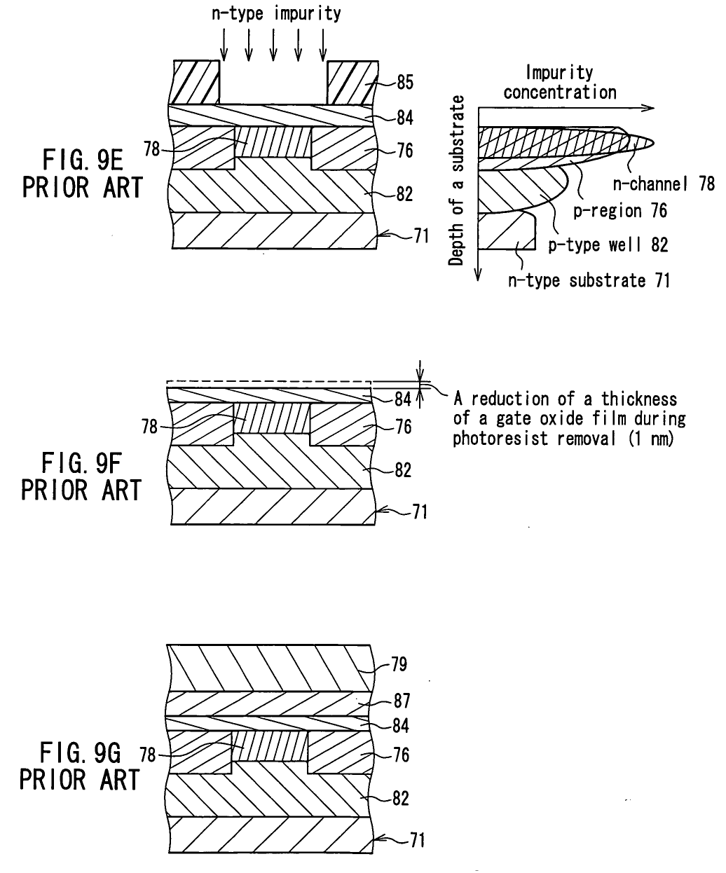

In Embodiment 1, the transfer channel 9 is formed after the formation of the first gate insulating film 6, similarly to the conventional manufacturing method shown by FIGS. 8A to 9G in the background of the invention. Therefore, the high-temperature heat treatment for forming the first gate insulating film 6 hardly causes the n-type impurity to diffuse toward the outside or to be absorbed by the first gate insulating film 6.

Therefore, also in Embodiment 1, a reduction in saturation charge capacity of the transfer channel 9 can be suppressed, and the occurrence of crystal defects in the transfer channel 9 can be reduced. Thereby, the occurrence of a white line noise caused by a local increase in dark current also can be suppressed.

Subsequently, as shown in FIG. 2F, the photoresist 8 for the transfer channel formation is removed completely. In the present embodiment, the removal of the photoresist 8 for the transfer channel formation is conducted by wet etching using a photoresist removal solution. Here, the protective film 7 becomes thin.

The photoresist removal solution used here provides a lower etch rate with respect to the protective film 7 than with respect to the first gate insulating film 6. More specifically, the etch rate of the photoresist removal solution with respect to the silicon nitride film is 0.5 nm per one photoresist removal process, and that with respect to the silicon oxide film is 1 nm per one photoresist removal process.

As mentioned above, the photoresist removal solution used in the step of FIG. 2F has a higher selectivity with respect to the protective film 7 than with respect to the first gate insulating film 6. Thus, an amount of the reduction of the thickness of the protective film 7 in one photoresist removal process is smaller than that of the first gate insulating film 84 in the step of FIG. 9F in the background of the invention.

As this photoresist removal solution, a photoresist removal solution (an etching solution) containing sulfuric acid and a hydrogen peroxide solution as main components, a photoresist removal solution (an etching solution) containing ammonia and a hydrogen peroxide solution as main components or the like may be used.

In Embodiment 1, the photoresist 8 for the transfer channel formation is removed using, for example, both of: a photoresist removal solution containing sulfuric acid and a hydrogen peroxide solution in a 5:1 volume ratio; and a photoresist removal solution containing ammonia and a hydrogen peroxide solution in a 1:1 volume ratio, which are prepared to be at 70° C. in temperature.

In this case, the thickness of the protective film 7 is reduced by approximately 0.5 nm in one photoresist removal process. Thus, the unevenness of the thickness of the protective film 7 is smaller than that of the first gate insulating film 84 in the step of FIG. 9F.

In Embodiment 1, the thickness of the protective film 7 is determined so that the protective film 7 may not be removed completely in photoresist removal processes to be conducted subsequently, considering an amount of the reduction of the thickness in one photoresist removal process and the number of photoresist processes that may be added subsequently.

Here, in Embodiment 1, the protective film 7 is preferably formed to be thin as long as it is not completely removed in the photoresist removal processes. This is because, when the n-type impurity is ion-implanted so as to form the n-type transfer channel 9, a shallow and sharp impurity profile can be realized with such a thin protective film by low-accelerated ion-implantation. If such an impurity profile can be realized, the charge transfer portion (the charge transfer device) can be decreased in size to be finer and can provide higher performance easily. More specifically, the thickness of the protective film 7 preferably ranges from 5 nm to 20 nm. In the present embodiment, the thickness thereof is set at approximately 15 nm.

Next, as shown in FIG. 2G, a second gate insulating film 10 is formed on the protective film 7. In Embodiment 1, the second gate insulating film 10 is a silicon nitride film that is the same as the protective film 7, and is formed by CVD. Therefore, a gate nitride film is composed of the second gate insulating film 10 and the protective film 7 in Embodiment 1.

A thickness of the second gate insulating film 10 is determined considering the amount of the reduction of the thickness of the protective film 7 so that a total thickness of the second gate insulating film 10 and the protective film 7 may be a required thickness of the gate nitride film, which is, for example, 40 nm.

Thereafter, as shown in FIG. 2H, a transfer electrode 11 is formed on the second gate insulating film 10, thereby manufacturing a solid-state imaging device and a charge transfer device. Note here that the transfer electrode 11 in the example shown by FIG. 2H corresponds to the first transfer electrode (see FIG. 7).

As mentioned above, the protective film 7 is formed on the first gate insulating film 6 that is formed of the silicon oxide film in Embodiment 1. Accordingly, in the process of removing the photoresist 8 for the transfer channel formation, the first gate insulating film 6 is protected by the protective film 7, whereby the reduction of the thickness of the first insulating film 6 can be suppressed.

Therefore, according to the manufacturing method of Embodiment 1, the total thickness of the gate insulating films can be controlled more easily, and the unevenness of the thickness can be decreased more, compared with the manufacturing method shown by FIGS. 8A to 9G in the background of the invention.

As mentioned above, in Embodiment 1, where the protective film 7 is the gate nitride film, the amount of the reduction of the thickness of the protective film 7 is smaller than that of the first gate insulating film 84 in the step of FIG. 9F in the background of the invention. Thus, the above-mentioned effect can be enhanced more.

Even in the case where the photoresist process is repeated due to occurrence of in-process discrepancies or further photoresist processes are added for ion-implantations of other impurities, the amount of the reduction of the thickness of the protective film 7 is small. Thus, the manufacturing method of Embodiment 1 can improve the tolerance for in-process discrepancies and can ease the limitation on the number of the ion-implantations to be conducted, compared with the method shown by FIGS. 8A to 9G in the background of the invention.

(Embodiment 2)

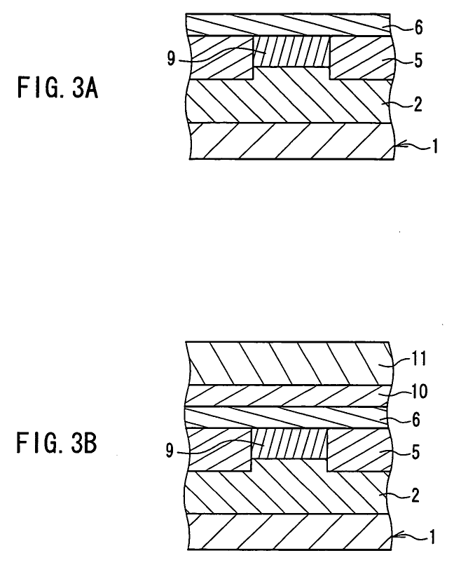

Next, the method for manufacturing a solid-state imaging device of Embodiment 2 will be described with reference to FIGS. 3A and 3B. FIGS. 3A and 3B are cross-sectional views showing respective steps in the method for manufacturing the solid-state imaging device of Embodiment 2 of the present invention. FIGS. 3A and 3B respectively show a series of the main steps. Similarly to FIGS. 1A to 2H, FIGS. 3A and 3B show the respective manufacturing steps, each showing a cross sectional configuration (see the line A-A in FIG. 7) of a region where the vertical CCD is provided on the semiconductor substrate.

The manufacturing method of Embodiment 2 is the same as that of Embodiment 1 except the process of forming the second gate insulating film 10 (the gate nitride film). That is, in Embodiment 2, the steps shown by FIGS. 3A and 3B are conducted in this order, subsequent to the steps shown by FIGS. 1A to 1D, 2E and 2F in Embodiment 1.

In Embodiment 2, the steps shown by FIG. 3A and 3B are conducted instead of the steps shown by FIGS. 2G and 2H in Embodiment 1. These steps will be specifically described below with reference to FIG. 3A and 3B.

Also in Embodiment 2, the steps shown by FIGS. 1A to 1D, 2E and 2F are conducted. Thus, since the first gate insulating film 6 is protected by the protective film 7, the reduction of the thickness of the first gate insulating film 6 is suppressed in the process of removing the photoresist 8 for the transfer channel formation (see FIG. 2E to 2H) also in Embodiment 2.

The thickness of the protective film 7 (see FIG. 2E to 2H) is actually reduced in these steps, but the amount of the reduction is smaller than that of the first gate insulating film 84 in the step of FIG. 9F, similarly to Embodiment 1. Thus, the manufacturing method of Embodiment 2 also can develop the tolerance for the in-process discrepancies and can ease the limitation on the number of the ion-implantations to be conducted.

Next, as shown in FIG. 3A, the protective film 7 is removed by wet etching using an etching solution that has remarkably high selectivity with respect to the first gate insulating film 6 (that is, having a higher etch rate with respect to the protective film 7 than with respect to the first gate insulating film 6). More specifically, an etching solution is used that provides an etch rate of 50 nm/min with respect to the silicon nitride film (the protective film 7), and an etch rate of 0.05 nm/min with respect to the silicon oxide film (the first gate insulating film 6).

Examples of such an etching solution include an etching solution containing phosphoric acid as a main component. In the step of FIG. 3A, the thickness of the first gate insulating film 6 is reduced by the etching solution. However, in the case of using the etching solution containing phosphoric acid as a main component, the thickness of the first gate insulating film 6 is reduced by only 0.1 nm or less in one etching process, and the removal of the protective film 7 is generally conducted only once through the whole manufacturing process. Therefore, the amount of the reduction of the thickness of the first insulating film 6 in the step of FIG. 3A is sufficiently small in comparison with that of the protective film 7 in Embodiment 1, and thus does not affect the control of the total thickness of the gate insulating films or the unevenness of the thickness.

Subsequently, the second gate insulating film 10 is formed on the first gate insulating film 6, and the transfer electrode 11 is further formed on the second gate insulating film 10. Also in Embodiment 2, the second gate insulating film 10 is a silicon nitride film formed by CVD, similarly to Embodiment 1.

Unlike in Embodiment 1, the protective film 7 is removed in Embodiment 2, which causes only a small reduction of the thickness of the first gate insulating film 6. Such a reduction of the thickness of the first gate insulating film 6 in Embodiment 2 is, however, sufficiently small, compared with that of the first gate insulating film 84 in the step of FIG. 9F in the background of the invention.

Therefore, similarly to Embodiment 1, the manufacturing method of Embodiment 2 can control the total thickness of the gate insulating films more easily, and can decrease the unevenness of the thickness more, compared with the manufacturing method shown by FIGS. 8A to 9G in the background of the invention.

(Embodiment 3)

The method for manufacturing the solid-state imaging device of Embodiment 3 will be described below. The solid-state imaging device manufactured in Embodiment 3 has the same configuration as those manufactured in Embodiments 1 and 2.

The solid-state imaging device manufactured in Embodiment 3 also includes a semiconductor substrate having a photodiode and a charge transfer portion. The charge transfer portion functions as a charge transfer device, and is composed of a vertical CCD and a horizontal CCD. The vertical CCD includes a first conductive-type transfer channel, and a second conductive-type region functioning as element isolation is formed on one or both sides of the transfer channel. Note here that the first conductive-type denotes n-type, and the second-conductive type denotes p-type in Embodiment 3 as well.

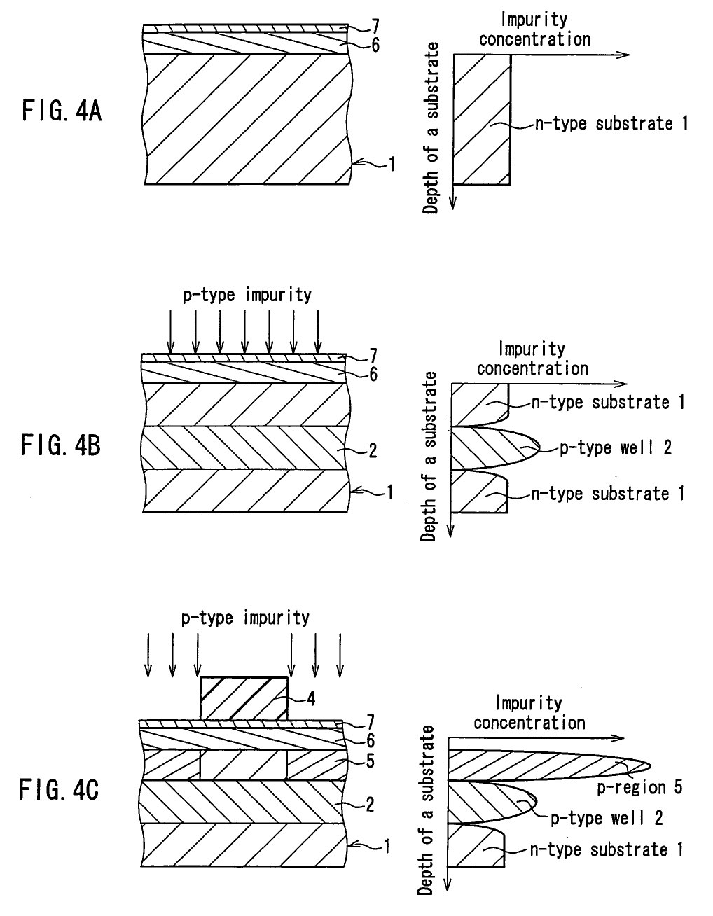

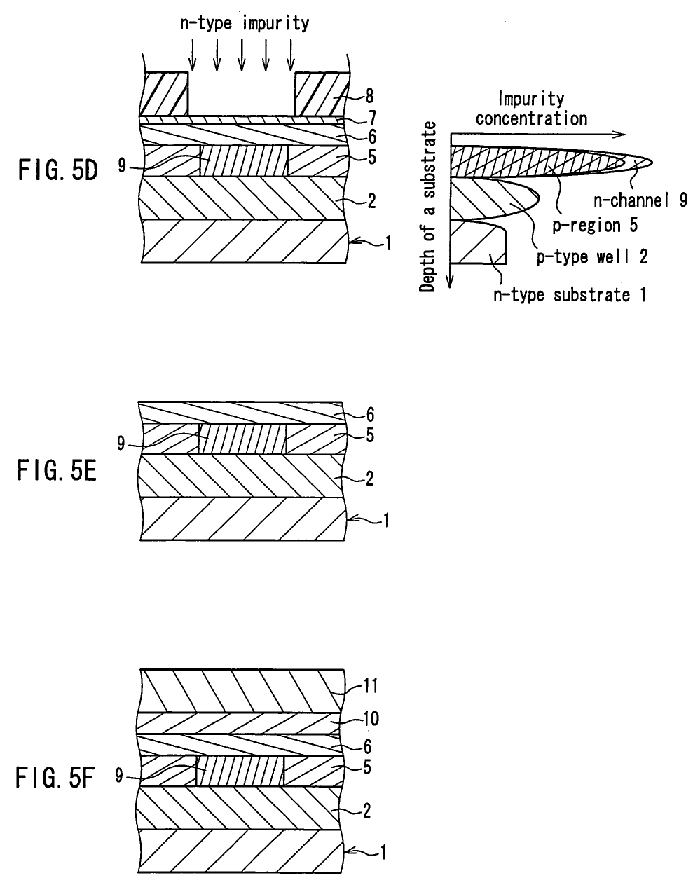

FIGS. 4A to 5F will be referred to for the following description. FIGS. 4A to 5F are cross-sectional views showing respective steps in the method for manufacturing the solid-state imaging device of Embodiment 3 of the present invention. FIGS. 4A to 4C respectively show a series of the main steps. FIGS. 5D to 5F respectively show a series of the main steps that are subsequent to the step of FIG. 4C.

Similarly to FIGS. 1A to 2H, FIGS. 4A to 5F show the respective manufacturing steps, each showing a cross sectional configuration (see the line A-A′ in FIG. 7) of a region where the vertical CCD is provided on the semiconductor substrate. FIGS. 4A to 4C and 5D include diagrams showing impurity distributions in a depth direction of the semiconductor substrate, with the accompanying cross-sectional views.

First, as shown in FIG. 4A, a first gate insulating film 6 is formed on a semiconductor substrate 1 by thermal oxidation or the like, and a protective film 7 is formed further on the first gate insulating film 6 by CVD or the like. Also in Embodiment 3, the semiconductor substrate 1 is a n-type substrate, and the first gate insulating film 6 is a silicon oxide film with a thickness of 30 nm.

The protective film 7 is a silicon nitride film. Similarly to Embodiment 1, a thickness of the protective film 7 is determined so that the protective film 7 may not be removed completely in photoresist removal processes to be conducted subsequently (see FIG. 4C to 5E) or photoresist removal processes that might be further added.

Similarly to Embodiment 1, the protective film 7 is formed to be thin as long as it is not completely removed. This is because, when an impurity is ion-implanted so as to form the below-described p-well 2, the p-region 5 and the transfer channel 9, a shallow and sharp impurity profile can be realized with such a thin protective film by low-accelerated ion-implantation. In Embodiment 3, the thickness of the protective film 7 is set at 15 nm.

Next, as shown in FIG. 4B, a photoresist (not shown in the figures) is formed on the protective film 7, and a part of the photoresist overlapping with a region where a p-type well 2 is to be formed is removed. Thereafter, a p-type impurity such as boron (B) is ion-implanted with an implantation energy of 300 keV and a dose of 1.0×10¹² ions/cm², for example. Thereby, the p-type well 2 is formed.

Next, as shown in FIG. 4C, the photoresist formed in the step of FIG. 4B is removed completely. This removal is performed using the photoresist removal solution used in the step of FIG. 2F in Embodiment 1. Therefore, the thickness of the protective film is reduced in this photoresist removal process, although the amount thereof is only 1 nm or less.

Subsequently, as shown in FIG. 4C, a photoresist 4 for p-region formation is formed on the protective film 7, and a part of the photoresist 4 for the p-region formation overlapping with a region where a p-region 5 is to be formed is removed.

Thereafter, as shown in FIG. 4C, a p-type impurity such as boron (B) is ion-implanted with an implantation energy of 40 keV and a dose of 1.0×10¹³ ions/cm², for example. Thereby, the p-region 5 is formed in a region shallower than the p-type well 2.

Subsequently, as shown in FIG. 5D, the photoresist 4 for the p-region formation is removed completely. The removal of the photoresist 4 is performed using the photoresist removal solution used in the step of FIG. 2F in Embodiment 1. Therefore, the thickness of the protective film is reduced in this photoresist removal process, although the amount thereof is 1 nm or less as well.

Next, as shown in FIG. 5D, a photoresist 8 for transfer channel formation is formed on the protective film 7, and then a part of the photoresist 8 for the transfer channel formation overlapping with a region where a transfer channel 9 is to be formed is removed. Thereafter, a n-type impurity such as phosphorus (P) and arsenic (As) is ion-implanted with an implantation energy of 150 keV and a dose of 1.0×10¹³ ions/cm², for example. Thereby, the n-type transfer channel (a n-channel) 9 is formed.

Also in Embodiment 3, the transfer channel 9 is formed after the formation of the first gate insulating film 6, similarly to the manufacturing method shown by FIGS. 8A to 9G in the background of the invention. Therefore, the high-temperature heat treatment for forming the first gate insulating film 6 hardly causes the n-type impurity to diffuse toward the outside or to be absorbed by the first gate insulating film 6.

Next, as shown in FIG. 5E, the photoresist 8 for the transfer channel formation is removed completely. The removal of the photoresist 8 is performed by the photoresist removal solution used in the step of FIG. 2F in Embodiment 1. Therefore, the thickness of the protective film 7 is reduced in this photoresist removal process, although the amount thereof is 1 nm or less as well.

Subsequently, as shown in FIG. 5E, the protective film 7 also is removed completely. The removal of the protective film 7 is performed by wet etching using an etching solution that has remarkably high selectivity with respect to the first gate insulating film 6 and contains, for example, phosphoric acid as a main component, similarly to the step of FIG. 3A in Embodiment 2.

Here, the thickness of the first gate insulating film 6 is reduced by the etching solution, similarly to the step of FIG. 3A in Embodiment 2. However, the thickness of the first gate insulating film 6 is reduced by only 0.1 nm or less in one etching process.

Subsequently, as shown in FIG. 5F, a second gate insulating film 10 is formed on the first gate insulating film 6, and a transfer electrode 11 is formed further on the second gate insulating film 10. Also in Embodiment 3, the second gate insulating film 10 is a silicon nitride film formed by .CVD, similarly to Embodiment 1.

As mentioned above, after forming the first gate insulating film 6 by the high-temperature heat treatment, the p-region 5 and the transfer channel 9 are formed in Embodiment 3. Thus, unlike the manufacturing method of Embodiment 1, 2 or the background of the invention, the p-region 5 does not diffuse due to the high-temperature heat treatment for forming the first gate insulating film 6.

Therefore, according to the manufacturing method of Embodiment 3, an effective channel width of the transfer channel 9 is not decreased, and a saturation charge capacity of the transfer channel 9 can be increased more, compared with the manufacturing methods of Embodiment 1, 2 and the background of the invention.

In addition, in Embodiment 3, the amount of the reduction of the thickness of the protective film 7 is larger than those in Embodiments 1 and 2, but the protective film 7 is completely removed before the formation of the second gate insulating film 10. Moreover, the thickness of the first gate insulating film 6 is reduced during the removal of the protective film 7, but an amount of the reduction is nearly equal to that in Embodiment 2. That is, similarly to Embodiment 2, this amount of the reduction is sufficiently small in comparison with that of the first gate insulating film 84 in the step of FIG. 9F, and thus does not affect the control of the total thickness of the gate insulating films or the unevenness of the thickness.

Therefore, similarly to Embodiments 1 and 2, the manufacturing method of Embodiment 3 can control the total thickness of the gate insulating films more easily, and can decrease the unevenness of the thickness more, compared with the manufacturing method shown by FIGS. 8A to 9G in the background of the invention.

In addition, similarly to Embodiments 1 and 2, the manufacturing method of Embodiment 3 can increase the tolerance for the in-process discrepancies and can ease the limitation on the number of the ion-implantations to be conducted, by virtue of the formation of the protective film 7.

In the example shown in FIGS. 4A to 5F, the p-region 5 is formed and the n-type transfer channel 9 is subsequently formed, but Embodiment 3 is not limited to this. In Embodiment 3, the p-region 5 may be formed after the formation of the n-type transfer channel 9. Among them, it is preferable to form the p-region 5 and subsequently form the n-type transfer channel 9 in the present embodiment because of the following reason.

In Embodiment 3, both the n-type impurity and the p-type impurity are ion-implanted through the protective film 7, which is damaged in each of the ion-implantation processes. Such damages degrade the durability of the protective film 7 against the photoresist removal solution, and a degree of the damage tends to be higher in accordance with a mass number of the ion-implanted impurity. In Embodiment 3, a mass number of the n-type impurity such as phosphorus (P, mass number: 30.97) and arsenic (As, mass number: 74.92) is larger than that of the p-type impurity such as boron (B, mass number: 10.81).

Therefore, in the case where the n-type impurity with the larger mass number is ion-implanted first, there is a risk that the protective film 7 is in a seriously damaged state when the p-type impurity is thereafter ion-implanted through the protective film 7. In this case, the reduction of the thickness of this damaged protective film 7 may be larger (for example, by 2 nm) than that of the undamaged protective film 7.

Furthermore, in such a case, when the amount of the reduction of the thickness of the protective film 7 becomes larger than expected, or the additional photoresist removal process is present due to the repeated photoresist processes, the protective film 7 may be removed completely, and then the thickness of the first gate insulating film 6 accordingly may be reduced by the photoresist removal solution. When the amount of the reduction of the thickness of the protective film 7 becomes larger, the unevenness of the thickness accordingly increases, which may cause the impurities to reach different diffusion depths in the process of the ion-implantation.

As mentioned above, it is therefore preferable to form the p-region 5 and subsequently form the n-type transfer channel 9 in Embodiment 3.

According to the present invention, the total thickness of the gate insulating films that are formed in the charge transfer portion (the charge transfer device) of the solid-state imaging device can be controlled easily, and the unevenness of the thickness can be decreased. Thereby, the saturation characteristics and the charge transfer characteristics of the charge transfer portion can be improved, thus leading to the enhancement of image qualities of the solid-state imaging device.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A method for manufacturing a solid-state imaging device that comprises a semiconductor substrate having a photodiode and a charge transfer portion, the charge transfer portion being provided with a transfer channel, comprising the steps of:
(a) forming a first gate insulating film in a region where the charge transfer portion is to be formed on the semiconductor substrate;
(b) forming a protective film on the first gate insulating film;
(c) forming a photoresist for transfer channel formation on the protective film and removing a part of the photoresist for the transfer channel formation overlapping with a region where the transfer channel is to be formed;
(d) forming the transfer channel below the first gate insulating film by ion-implantation of an impurity using the photoresist for the transfer channel formation as a mask;
(e) removing the photoresist for the transfer channel formation; and
(f) forming a second gate insulating film on the protective film after the step (e).

2. The method for manufacturing a solid-state imaging device according to claim 1, wherein the protective film is removed after removing the photoresist for the transfer channel formation in the step (e), and the second gate insulating film is formed on the first gate insulating film in the step (f).

3. The method for manufacturing a solid-state imaging device according to claim 2, wherein the protective film is removed using an etching solution that provides a higher etch rate with respect to the protective film than with respect to the first gate insulating film.

4. The method for manufacturing a solid-state imaging device according to claim 1, wherein the transfer channel is first conductive-type, to which a first conductive-type impurity is ion-implanted in the step (d).

5. The method for manufacturing a solid-state imaging device according to claim 4, the solid-state imaging device including a second conductive-type region formed on one or both sides of the transfer channel of the semiconductor substrate, further comprising the steps of:
(g) forming a photoresist for second conductive-type region formation on the protective film and removing a part of the photoresist for the second conductive-type region formation overlapping with a region where the second conductive-type region is to be formed;
(h) forming the second conductive-type region below the first gate insulating film by ion-implantation of a second conductive-type impurity using the photoresist for the second conductive-type region formation as a mask; and
(i) removing the photoresist for the second conductive-type region formation, wherein the steps (g) to (i) are conducted after the step (b) or (e) and before the step (f).

6. The method for manufacturing a solid-state imaging device according to claim 5,
wherein the steps (g) to (i) are conducted after the steps (c) to (e) when a mass number of the first conductive-type impurity is smaller than a mass number of the second conductive-type impurity, and
the steps (c) to (e) are conducted after the steps (g) to (i) when a mass number of the first conductive-type impurity is larger than a mass number of the second conductive-type impurity.

7. The method for manufacturing a solid-state imaging device according to claim 1, wherein the protective film is formed to have a thickness smaller than a thickness of the first gate insulating film and a thickness of the second gate insulating film in the step (b).

8. The method for manufacturing a solid-state imaging device according to claim 1, wherein the photoresist for the transfer channel formation is removed using a photoresist removal solution that provides a lower etch rate with respect to the protective film than with respect to the first gate insulating film in the step (e).

9. The method for manufacturing a solid-state imaging device according to claim 5,
wherein the photoresist for the second conductive-type region formation is removed using a photoresist removal solution that provides a lower etch rate with respect to the protective film than with respect to the first gate insulating film in the step (i).

10. The method for manufacturing the solid-state imaging device according to claim 1, wherein
the first gate insulating film is formed of a silicon oxide film in the step (a),
the protective film is formed of a silicon nitride film in the step (b), and the second gate insulating film is formed of a silicon nitride film in the step (f).
